(19) United States
(12) Patent Application Publication
(10) Pub. No.: US 2023/0314516 A1
(43) Pub. Date: Oct. 5, 2023

(54) DISCHARGE VOLTAGE GRAPH PREDICTION METHOD AND BATTERY SYSTEM USING THE SAME

(71) Applicant: LG ENERGY SOLUTION, LTD., Seoul (KR)

(72) Inventors: Sun Jong LEE, Daejeon (KR); Cheoltaek KIM, Daejeon (KR)

(73) Assignee: LG ENERGY SOLUTION, LTD., Seoul (KR)

(21) Appl. No.: 18/025,110

(22) PCT Filed: Dec. 23, 2021
(86) PCT No.: PCT/KR2021/019714

§ 371 Date: Mar. 7, 2023

(30) Foreign Application Priority Data
Jan. 8, 2021 (KR) 10-2021-0002661

(51) Int. Cl. G01R 31/367; H01M 10/48; G01R 31/382; G01R 31/36; G01R 31/396

(52) U.S. Cl. CPC G01R 31/367; H01M 10/48; G01R 31/382; G01R 31/3648; G01R 31/396; H01M 2010/4271

(57) ABSTRACT

A method for predicting a constant current discharge graph for a battery cell according to one feature of the invention includes: measuring a first time required for the battery cell voltage to decrease to a first discharge limit voltage by a first constant current discharge; measuring a second time required for the battery cell voltage to decrease to a second discharge limit voltage by a second constant current discharge; and calculating a proportional constant and an index parameter in the relationship between the constant current and the discharge time during a discharging based on the first constant current and the first time, and the second constant current and the second time.

### CROSS-REFERENCE TO RELATED APPLICATION

This application claims priority to and the benefit of Korean Patent Application No. 10-2021-0002661 filed in the Korean Intellectual Property Office on Jan. 8, 2021, the entire contents of which are incorporated herein by reference.

### TECHNICAL FIELD

The present disclosure relates to a discharge voltage graph prediction method and a battery system using the same.

### BACKGROUND ART

In the prior art, where there is no discharge voltage graph prediction technology for lithium ion secondary batteries, direct experiments were conducted for each discharge current to obtain a discharge voltage graph, and a discharge voltage graph of a lithium ion reachable battery for the corresponding discharge current was obtained. The discharge voltage graph is a graph of the change in the battery cell voltage depending on a passage of time when being discharged with a predetermined constant current, it is necessary to measure a discharge limit current at a predetermined time, a discharge resistance at a predetermined time, or a discharge power at a predetermined time.

### DISCLOSURE

### Technical Problem

The present disclosure is to provide a discharge voltage graph prediction method that may predict the discharge voltage graph and a battery system using the same in a case of being discharged with an arbitrary constant current without information about the discharge voltage graph through experiments.

### Technical Solution

A method for predicting a constant current discharge graph for a battery cell according to a feature of the invention includes: measuring a first time required for the battery cell voltage to decrease to a first discharge limit voltage by a first constant current discharge; measuring a second time required for the battery cell voltage to decrease to a second discharge limit voltage by a second constant current discharge; and calculating a proportional constant and an index parameter in the relationship between the constant current and the discharge time during discharging based on the first constant current and the first time, and the second constant current and the second time. The first discharge limit voltage is a voltage obtained by subtracting the first voltage drop due to the first constant current and the internal resistance of the battery cell from the discharge reference voltage when the discharge current is 0, and the second discharge limit voltage is a voltage obtained by subtracting the second voltage drop due to the second constant current and the internal resistance of the battery cell from the discharge reference voltage.

The method of predicting the constant current discharge graph for the battery cell may further include predicting the time required for the voltage of the battery cell to reach a third discharge limit voltage by using the proportional constant and the index parameter when discharging the battery cell with the third constant current, and the third discharge limit voltage may be a voltage obtained by subtracting the third voltage drop due to the third constant current and the internal resistance of the battery cell from the discharge reference voltage.

The method of predicting the constant current discharge graph for the battery cell may further include: changing the discharge reference voltage; measuring a third time required for the battery cell voltage to decrease to a fourth discharge limit voltage by a fourth constant current discharge; measuring a fourth time required for the battery cell voltage to decrease to a fifth discharge limit voltage by a fifth constant current discharge; and calculating the proportional constant and the index parameter in the relationship between the discharge current and the time based on the fourth constant current and the third time, and the fifth constant current and the fourth time, the fourth discharge limit voltage may be a voltage obtained by subtracting the fourth voltage drop dur to the third constant current and the internal resistance of the battery cell from the changed discharge reference voltage, and the fifth discharge limit voltage may be a voltage obtained by subtracting the fifth voltage drop due to the fourth constant current and the internal resistance of the battery cell from the changed discharge reference voltage.

The method of predicting the constant current discharge graph for the battery cell may further include predicting the time required for the voltage of the battery cell to reach the sixth discharge limit voltage by using the proportional constant and the index parameter when discharging the battery cell with the sixth constant current, and the sixth discharge limit voltage is a voltage obtained by subtracting a sixth voltage drop due to the sixth constant current and the internal resistance of the battery cell from the changed discharge reference voltage.

A battery system according to another feature of the invention includes: a plurality of battery cells; and a battery management system for predicting a discharge time required for each of a plurality of battery cell voltages to reach a corresponding discharge limit voltage during a constant current discharge. The battery management system may store information about a proportional constant and an index parameter defining a relationship between a constant current and a discharge time, a proportional constant and an index parameter about one among a plurality of battery cells may be calculated based a first constant current and a first time, and a second constant current and a second time after measuring a first time required for the battery cell voltage to decrease to a first discharge limit voltage by a first constant current discharge and measuring a second time required for the battery cell voltage to decrease to a second discharge limit voltage by a second constant current discharge, and the first discharge limit voltage may be a voltage obtained by subtracting the first voltage drop due to the first constant current and the internal resistance of the battery cell from the discharge reference voltage when the discharge current is 0, and the second discharge limit voltage may be a voltage obtained by subtracting the second voltage drop due to the second constant current and the internal resistance of the battery cell from the discharge reference voltage.

The battery management system may predict the time required for the voltage of the battery cell to reach a third discharge limit voltage by using the proportional constant and the index parameter when discharging the battery cell with the third constant current, and the third discharge limit voltage may be a voltage obtained by subtracting the third voltage drop due to the third constant current and the internal resistance of the battery cell from the discharge reference voltage.

The SOC of the battery cell and the temperature of the cell at the time of the discharge start may be the same by the first constant current, the second constant current, and the third constant current.

The relation between the discharge current and the time may be I=a*t^{b}, where I may be the discharge current, t may be the time, a may be the proportional constant, and b may be the index parameter.

### Advantageous Effects

If discharge occurs with a constant current that has not been tested, it is difficult to predict whether the battery cell has any kind of discharge voltage graph. An exemplary embodiment of the present invention may predict the discharge voltage graph when being discharged with an arbitrary constant current.

### BRIEF DESCRIPTION OF THE DRAWINGS

FIG. 1 is a graph to explain a method of predicting a discharge voltage graph according to an exemplary embodiment.

FIG. 2 is a flowchart showing a method of determining a proportional constant and an index parameter between a constant current and a discharge time according to an exemplary embodiment.

FIG. 3 is a discharge voltage graph predicted when being discharged with a predetermined current according to an exemplary embodiment.

FIG. 4 is a graph comparing a discharge voltage test result and a prediction result for each discharge current.

FIG. 5 is a graph comparing a discharge voltage test result and a prediction result for each discharge current.

FIG. 6 is a view showing a battery system to which a method of predicting a discharge voltage graph according to an exemplary embodiment is applied.

### MODES FOR INVENTION

Hereinafter, embodiments disclosed in the present specification will be described in detail with reference to the accompanying drawings. In the present specification, the same or similar components will be denoted by the same or similar reference numerals, and an overlapped description thereof will be omitted. The terms “module” and “unit” for components used in the following description are used only in order to easily make a specification. Therefore, these terms do not have meanings or roles that distinguish them from each other in themselves. Further, in describing embodiments of the present specification, when it is determined that a detailed description of the well-known art associated with the present invention may obscure the gist of the present invention, it will be omitted. In addition, the accompanying drawings are provided only in order to allow embodiments disclosed in the present specification to be easily understood and are not to be interpreted as limiting the spirit disclosed in the present specification, and it is to be understood that the present invention includes all modifications, equivalents, and substitutions without departing from the scope and spirit of the present invention.

Terms including ordinal numbers such as first, second, and the like will be used only to describe various components and are not to be interpreted as limiting these components. The terms are only used to differentiate one component from other components.

It is to be understood that when one component is referred to as being “connected” or “coupled” to another component, it may be connected or coupled directly to another component or be connected or coupled to another component with the other component intervening therebetween. On the other hand, it is to be understood that when one component is referred to as being “connected or coupled directly” to another component, it may be connected to or coupled to another component without another component intervening therebetween.

It will be further understood that terms “comprise” or “have” used in the present specification specify the presence of stated features, numerals, steps, operations, components, parts, or a combination thereof, but do not preclude the presence or addition of one or more other features, numerals, steps, operations, components, parts, or a combination thereof.

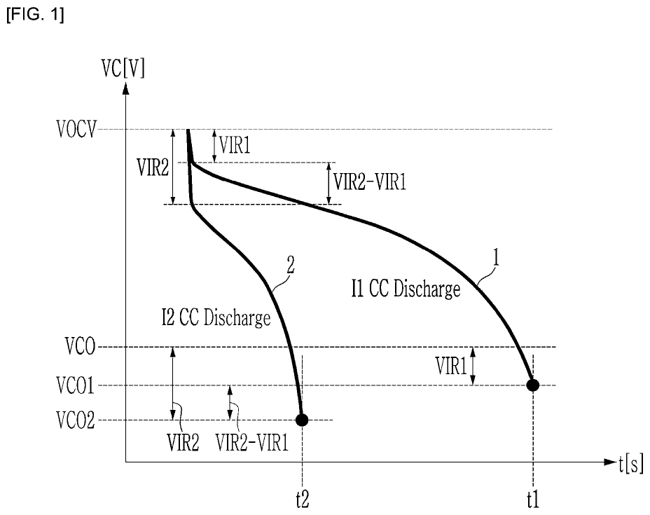

FIG. 1 is a graph to explain a method of predicting a discharge voltage graph according to an exemplary embodiment.

FIG. 1 shows a change of a battery cell voltage depending on a passage of a time when performing a discharge with different constant current (CC) from each other in a condition of a predetermined start SOC (State of Charge) and a predetermined start temperature.

First, a discharge voltage curve 1 of FIG. 1 is a graph showing the change in the battery cell voltage (VC) when being discharged with a constant current I1, and a discharge voltage curve 2 shows the change of the battery cell voltage (VC) when being discharged with a constant current I2.

In FIG. 1, “VCO” may be arbitrarily selected as the discharge reference voltage when the discharge current is 0. “VCO1” is the voltage (VCO−VIR1) obtained by subtracting the voltage drop (VIR1=R*I1) from the discharge reference voltage (VCO) when the constant current I1 flows through the battery cell, and “VCO2” is the voltage (VCO−VIR2) obtained by subtracting the voltage drop (VIR2=R*I2) from the discharge reference voltage (VCO) when the constant current I2 flows through the battery cell. That is, VCO1 is the discharge limit voltage when the discharge current is I1, and VOC2 is the discharge limit voltage when the discharge current is I2. In the condition that the start SOC and the start temperature are the same, respectively, when the CC discharge is performed, VCO1, VCO2, and VCO have the relationship as shown in Equation 1. The discharge limit voltage means a minimum voltage at which the battery cell voltage is capable of being reduced during the discharge, and when the battery cell is discharged to a voltage that is lower than the discharge limit voltage, the battery cell may be damaged.

VCO1+R*I1=VCO2+R*I2=VCO [Equation 1]

As shown in FIG. 1, when the discharge starts, the battery cell voltage VC rapidly decreases from the open circuit voltage (OCV) VOCV to the voltage drop caused by the constant current and the resistance of the battery cell, and then decreases depending on the lapse of time. The battery cell voltage decreases at the discharge start by the voltage drop R*I1 due to the constant current I1 and the battery cell resistance R, and the battery cell voltage decreases depending on the lapse of time, and when the time t1 elapses, the discharge limit voltage VCO1 is reached. The battery cell voltage decreases at the discharge start by the voltage drop R*I2 due to the constant current I2 and the battery cell resistance R, and the battery cell voltage decreases depending on the lapse of time, and when the time t2 elapses, the discharge limit voltage VCO2 is reached.

The relationship between the constant current “I” and the discharge time “t” when the battery cell is discharged satisfies Equation 2 below.

I=a*t^{b} [Equation 2]

In Equation 2, “a” and “b” are the proportional constant and the index parameter between the constant current and the discharge time during the discharge.

If Equation 2 is summarized with respect to time, it is as shown in Equation 3.

$$t = {( \frac{I}{a} )}^{\frac{1}{b}} \qquad [ Equation 3 ]$$

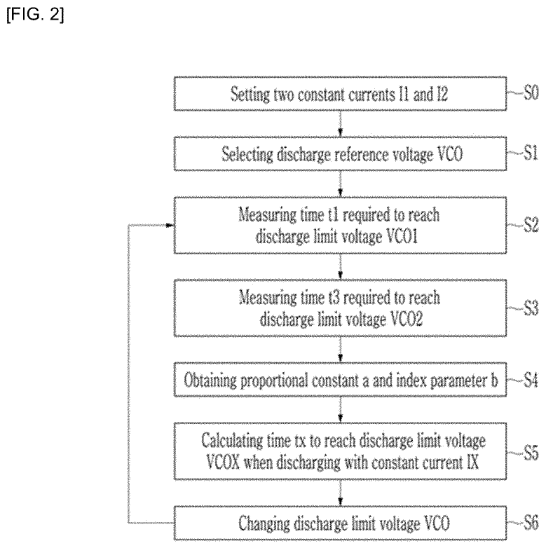

FIG. 2 is a flowchart showing a method of determining a proportional constant and an index parameter between a constant current and a discharge time according to an exemplary embodiment.

First, two constant currents I1 and I2 are set (S0).

Next, the discharge reference voltage VCO is selected (S1).

When discharging with the constant current I1, the battery cell voltage VC decreases and then the time t1 required to reach the discharge limit voltage (VCO1=VCO−R*I1) is measured (S2).

Then, when discharging with the constant current I2, the battery cell voltage VC decreases and then the time t2 required to reach the discharge limit voltage (VCO2=VCO−R*I2) is measured (S3).

By substituting I1 and t1, and I2 and t2 obtained through the step (S2) and the step (S3) into Equation 2, two simultaneous equations are obtained, and the proportional constant “a” and the index parameter “b” are obtained by solving two simultaneous equations (S4).

When the proportional constant “a” and the index parameter “b” are applied to Equation 3, and the discharge is performed with an arbitrary constant current Ix, the time tx to reach the discharge limit voltage (VCOx) of which the voltage drop (R*Ix) is subtracted from the discharge reference voltage (VCO) is calculated (S5).

The discharge reference voltage (VCO) is changed (S6) and the steps (S2 to S5) are repeated.

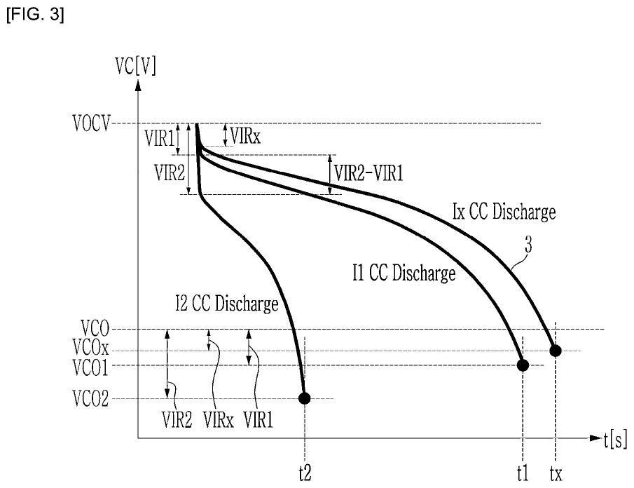

FIG. 3 is a discharge voltage graph predicted when discharge occurs with a predetermined current according to an exemplary embodiment.

To compare the times to reach the discharge limit voltage for the different constant currents I1 and I2, respectively, and the arbitrary current Ix, FIG. 3 shows together the discharge voltage graph for each of the constant currents I1 and I2.

As shown in FIG. 3, in the discharge voltage graph 3 according to an arbitrary constant current (Ix), if the discharge starts, the battery cell voltage (VC) rapidly decreases from the open circuit voltage (OCV) (VOCV) by the voltage drop (VIRx=R*Ix) due to the corresponding constant current and the resistance of the battery cell, and the battery cell voltage decreases depending on the lapse of time and reaches the discharge limit voltage (VCOx) when the time tx elapses.

FIG. 4 is a graph comparing a discharge voltage test result and a prediction result for each discharge current.

In FIG. 4, the thin solid lines 41-46 show the discharge voltage graph according to the test result, and the thick solid lines 47-50 show the predicted discharge voltage graph.

The start SOC and start temperature are all the same SOC 60% and 25° C.

In FIG. 4, “C” means “C-rate”, and the current corresponding to the reference capacity of the battery cell corresponds to 1 C-rate. For example, in the case of the battery cell having the reference capacity of 100 Ampere-hours (Ah), 1 C means 100 A, and 2 C means 200 A. Based on the discharge voltage graphs 42 and 45 in the discharge experiment for the constant current 3 C and 4.5 C, respectively, shown in FIG. 4, the proportional constant “a” and index parameter “b” were calculated according to the method described above.

In FIG. 4, when discharging with the constant current 2.5 C, 3.5 C, 4 C, and 5 C, respectively, the result of predicting the discharge voltage has an average error of 1 mV-3 mV obtained through the actual experiment for the discharge voltage and a maximum error range of 3 mV-8 mV. That is, as shown in FIG. 4, it may be seen that the prediction error compared to the battery cell voltage forms a significantly low value.

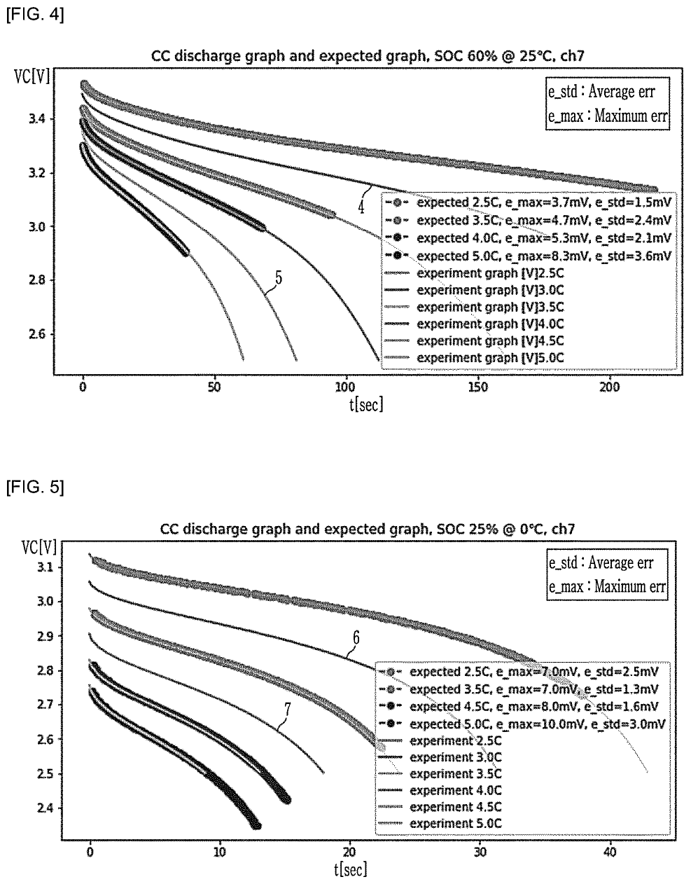

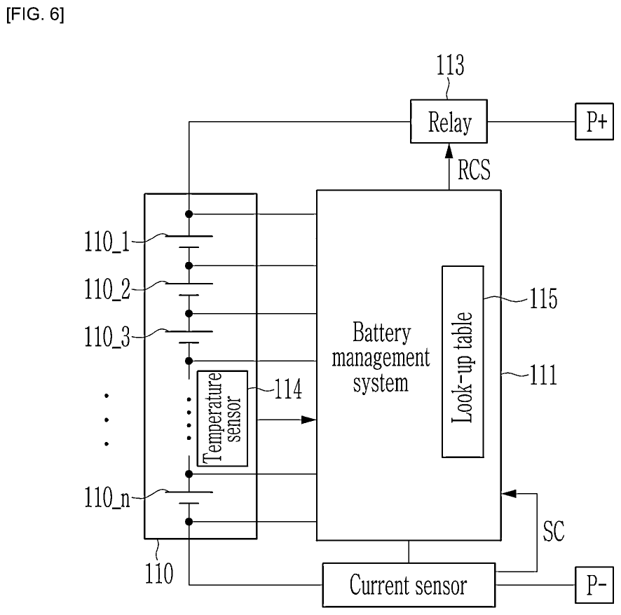

FIG. 5 is a graph comparing a discharge voltage test result and a prediction result for each discharge current.

In FIG. 5, the thin solid lines 51-56 show the discharge voltage graph according to the test result, and the thick solid lines 57-60 shows the predicted discharge voltage graph.

The start SOC and start temperature are all the same at SOC 25% and 0° C.

Based on the discharge voltage curves 53 and 55 in the discharge experiment for the constant current 2.5 C and 3.5 C, respectively, shown in FIG. 5, the proportional constant “a” and the index parameter “b” were calculated according to the method described above.

In FIG. 5, when discharging with the constant current 2.5 C, 3.5 C, 4 C, and 5 C, respectively, the results of predicting the discharge voltage have an average error of 1 mV-3 mV obtained through the actual experiment for the discharge voltage and a maximum error range of 7 mV-10 mV. That is, in the graph shown in FIG. 5, it may be seen that the prediction error compared to the battery cell voltage forms a significantly low value.

In this way, the number of experiments for acquiring the discharge voltage graph is reduced, and the duration of the experiment is reduced. In addition, since it is possible to predict the constant current discharge voltage graph, it is possible to predict the discharge limit current for any time (x seconds elapsed from the start of the discharge), the discharge resistance for any time, or the discharge power for any time as well as the measurement. The discharge limit current means the constant current when the battery cell voltage reaches the discharge limit voltage from the initial voltage for x seconds in the discharge voltage curve. The discharge resistance is calculated by dividing the value obtained by subtracting the battery cell voltage at x seconds from the initial discharge voltage of the battery cell by the discharge current. The discharge power may be calculated by dividing the area up to x seconds in the discharge voltage curve by x seconds.

FIG. 6 is a view showing a battery system to which a method of predicting a discharge voltage graph according to an exemplary embodiment is applied.

As shown in FIG. 6, a battery system 100 includes a battery 110 including a plurality of battery cells 110_1 to 110_n connected in series, a battery management system (BMS) 111, a current sensor 112, a relay 113, and a temperature sensor 114.

The current sensor 112 may detect a current (hereinafter, a battery current) flowing through the battery 110 and transmitting a current detection signal SC indicating the detected battery current to the BMS 111. In FIG. 6, the current sensor 112 is connected between a negative electrode of the battery 110 and an output terminal (P−) of the battery 110, but unlike that shown in FIG. 6, it may be connected between the positive electrode of the battery 110 and the output terminal (P+) of the battery 110.

The temperature sensor 114 may be positioned inside the battery 110 to measure or estimate the temperature of each of a plurality of battery cells. The temperature sensor 114 may transmit a signal indicating the temperature of each of a plurality of battery cells to the BMS 111.

The BMS 111 may measure the cell voltage of a plurality of battery cells 110_1 to 110_n and measure the battery voltage that is a voltage between both terminals of the battery 110, a temperature of each of a plurality of battery cells 110_1 to 110_n, etc., and may predict the SOC of each of a plurality of battery cells 110_1 to 110_n and predict an internal resistance of each of a plurality of battery cells 110_1 to 110_n based on a plurality of battery cell voltages, the battery current, and the battery cell temperature. The method for estimating the SOC and the internal resistance is a known technique, and various methods may be applied to the present invention. The BMS 111 may control the charging and discharging based on the estimated SOC, control a balancing operation for a plurality of battery cells based on a plurality of battery cell voltages and the battery cell temperatures, and control a protection operation in a case that an overvoltage, an overcurrent, or a high temperature occur.

The relay 114 is connected between the output terminal (P+) of the battery 110 and the positive electrode of the battery 110, and opens or closes according to the relay control signal (RCS) of the BMS 111. The relay 114 may be closed according to the relay control signal (RCS) of an on-level and open according to the relay control signal (RCS) of an off-level.

According to the prediction method of the discharge voltage graph according to the discharge by the constant current described above, the BMS 111 is possible to predict the time required to reach the discharge limit voltage (VCO_i, i is a natural number from 1 to n) corresponding to each of a plurality of battery cells 110_1 to 110_n. For this, the BMS 111 may store the look-up table 115, which stores an information on the proportional constant and index parameters for each SOC and battery temperature at the start of the discharge operation.

When the discharge is performed with an arbitrary constant current (Ix) for any one of a plurality of battery cells 110_1-110_n, the BMS 111 may predict the time required to reach the discharge limit voltage (VCOx) for the corresponding battery cell voltage by using the stored proportional constant and index parameter, and Equation 3. In this case, the BMS 111 may read the proportional constant and index parameter corresponding to the same SOC and temperature as the SOC and temperature of the corresponding battery cell from the look-up table 115.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

1. A method for predicting a constant current discharge graph for a battery cell, the method comprising:
measuring a first discharge time required for a voltage of the battery cell to decrease to a first discharge limit voltage by a discharge of a first constant current;
measuring a second discharge time required for the voltage of the battery cell to decrease to a second discharge limit voltage by a discharge of a second constant current; and
calculating a proportional constant and an index parameter in a relationship between a constant discharge current and a discharge time during discharging of the battery cell based on the first constant current and the first discharge time and on the second constant current and the second discharge time,
wherein the first discharge limit voltage is a voltage obtained by subtracting a first voltage drop due to the first constant current and an internal resistance of the battery cell from a discharge reference voltage with a discharge current of 0, and
wherein the second discharge limit voltage is a voltage obtained by subtracting a second voltage drop due to the second constant current and the internal resistance of the battery cell from the discharge reference voltage.

2. The method of claim 1, further comprising:
predicting a discharge time required for the voltage of the battery cell to reach a third discharge limit voltage by using the proportional constant and the index parameter when discharging the battery cell with a third constant current,
wherein the third discharge limit voltage is a voltage obtained by subtracting a third voltage drop due to the third constant current and the internal resistance of the battery cell from the discharge reference voltage.

3. The method of claim 2, wherein:
a state of charge (SOC) of the battery cell and a temperature of the battery cell at a start of the discharge stat are the same for the first constant current, the second constant current, and the third constant current.

4. The method of claim 2, further comprising:
changing the discharge reference voltage;
measuring a third discharge time required for the voltage of the battery cell to decrease to a fourth discharge limit voltage by a discharge of a fourth constant current;
measuring a fourth discharge time required for the voltage of the battery cell to decrease to a fifth discharge limit voltage by a discharge of a fifth constant current; and
calculating the proportional constant and the index parameter in the relationship between the discharge current and the discharge time based on the fourth constant current and the third discharge time and on the fifth constant current and the fourth discharge time,
wherein the fourth discharge limit voltage is a voltage obtained by subtracting a fourth voltage drop due to the third constant current and the internal resistance of the battery cell from the changed discharge reference voltage, and
wherein the fifth discharge limit voltage is a voltage obtained by subtracting a fifth voltage drop due to the fourth constant current and the internal resistance of the battery cell from the changed discharge reference voltage.

5. The method of claim 4, further comprising:
predicting a discharge time required for the voltage of the battery cell to reach a sixth discharge limit voltage by using the proportional constant and the index parameter when discharging the battery cell with a sixth constant current,
wherein the sixth discharge limit voltage is a voltage obtained by subtracting a sixth voltage drop due to the sixth constant current and the internal resistance of the battery cell from the changed discharge reference voltage.

6. The method of claim 1, wherein the relation between the constant discharge current and the discharge time is:
I=a*t^{b},
wherein I is the constant discharge current, t is the discharge time, a is the proportional constant, and b is the index parameter.

7. A battery system, comprising:
a plurality of battery cells; and
a battery management system for predicting a discharge time required for a voltage of a battery cell among the plurality of battery cells to reach a corresponding discharge limit voltage during a constant current discharge,
wherein the battery management system stores information about a proportional constant and an index parameter defining a relationship between a constant discharge current and a discharge time,
wherein the proportional constant and the index parameter for the battery cell are calculated based on a first constant current and a first discharge time and on a second constant current and a second discharge time, the first discharge time being a discharge time required for the voltage of the battery cell to decrease to a first discharge limit voltage by a discharge of the first constant current and the second discharge time being a discharge time required for the voltage of the battery cell to decrease to a second discharge limit voltage by a discharge of the second constant current, and
wherein the first discharge limit voltage is a voltage obtained by subtracting a first voltage drop due to the first constant current and an internal resistance of the battery cell from a discharge reference voltage with a discharge current of 0, and the second discharge limit voltage is a voltage obtained by subtracting a second voltage drop due to the second constant current and the internal resistance of the battery cell from the discharge reference voltage.

8. The battery system of claim 7, wherein:
the battery management system is configured to predict a discharge time required for the voltage of the battery cell to reach a third discharge limit voltage by using the proportional constant and the index parameter when discharging the battery cell with a third constant current, and
the third discharge limit voltage is a voltage obtained by subtracting a third voltage drop due to the third constant current and the internal resistance of the battery cell from the discharge reference voltage.

9. The battery system of claim 8, wherein:
a state of charge (SOC) of the battery cell and a temperature of the battery cell at a start of the discharge tat are the same for the first constant current, the second constant current, and the third constant current.

10. The battery system of claim 7, wherein the relation between the constant discharge current and the discharge time is:
I=a*t^{b},
wherein I is the constant discharge current, t is the discharge time, a is the proportional constant, and b is the index parameter.
